(19) United States
(12) Patent Application Publication
(10) Pub. No.: US 2008/0279656 A1
(43) Pub. Date: Nov. 13, 2008

(54) Transfer apparatus

(75) Inventors: Takafumi URATANI, Osaka-shi (JP); Daisuke SADO, Osaka-shi (JP); Hideki MATSUO, Osaka-shi (JP)

Correspondence Address: HAMRE, SCHUMANN, MUELLER & LARSON, P.C., P.O. BOX 2902, MINNEAPOLIS, MN, 55402-0902, US

(73) Assignee: DAIHEN Corporation, Osaka-shi (JP)

(21) Appl. No.: 12/151,223

(22) Filed: May 5, 2008

(30) Foreign Application Priority Data
May 10, 2007 (JP) 2007-125504

(51) Int. Cl. H01L 21/67

(52) U.S. Cl. 414/217

(57) ABSTRACT

A transfer apparatus includes a stationary base, a swivel rotatably supported by the stationary base, and a linear movement mechanism supported by the swivel and including guide rails. Hands for carrying works are supported by the guide rails and movable along a horizontal straight travel path by the operation of the linear movement mechanism. A heat reflector is provided between the hands and the guide rails. A refrigerant circulation channel includes annular spaces for ensuring constant communication between a passage on the side of the stationary base and a passage on the side of the swivel. The refrigerant circulation channel includes cooling pipes held in contact with the heat reflector.

### BACKGROUND OF THE INVENTION

1. Field of the Invention

The present invention relates to a transfer apparatus for transferring a work such as a thin plate. In particular, the present invention relates to a transfer apparatus suitable for transferring a heated work in a vacuum.

2. Description of the Related Art

An example of transfer apparatus for transferring a work in the form of a thin plate in a vacuum is described in JP-A-2005-125479. As shown in FIGS. 17-25 of this Japanese patent document, the transfer apparatus includes a pair of link arm mechanisms provided on a swivel. Each of the link arm mechanisms includes an end provided with a hand for horizontally holding a work in the form of a plate such as a glass substrate for a liquid crystal display panel. When a swivel rotates around a rotation axis on a stationary base, the paired link arm mechanisms rotate correspondingly. When the link arm mechanism is driven, the work held by the hand moves linearly within a horizontal plane. Thus, the work is transferred from a certain position to another position. The swivel supports a guide rail via a guide member. The guide rail serves to support and guide the hand for movement in a predetermined direction when the link arm mechanism is driven. This arrangement ensures that the hand holding the work is moved linearly with a stable posture.

The above-described transfer apparatus is often used for carrying in or out a work relative to a process chamber in manufacturing a liquid crystal display panel, for example. Specifically, the transfer apparatus may be used for transferring a heated glass substrate in a vacuum in a clean process, for example.

However, the conventional transfer apparatus may not stand the use to transfer a heated work in a vacuum in view of the thermal condition. Specifically, to use the transfer apparatus for such a purpose, the swivel may be placed in an inner space of a transfer chamber held in a vacuum state, while the stationary base is placed in the air. In this case, when the hand holds the heated work to be transferred, the guide rail positioned adjacent to the hand may be deformed due to the heat radiated from the work, which makes it difficult to perform accurate transferring.

### SUMMARY OF THE INVENTION

An object of the present invention, which is proposed under the circumstances described above, is to provide a transfer apparatus capable of dissolving or lessening problems caused by the heat radiated from a work in transferring a heated work in a vacuum.

According to the present invention, there is provided a transfer apparatus comprising: a stationary base; a swivel rotatably supported by the stationary base; a linear movement mechanism supported by the swivel and including a guide rail; a hand supported by the guide rail for transferring a work along a horizontal straight travel path by operation of the linear movement mechanism; a heat reflector for reflecting heat from the hand, the heat reflector being arranged at least between the hand and the guide rail; and a refrigerant circulation channel extending through both the stationary base and the swivel.

The refrigerant circulation channel includes a stationary base side passage provided at the stationary base, a swivel side passage provided at the swivel, and a connection space for providing communication between the stationary base side passage and the swivel side passage regardless of a rotational position of the swivel relative to the stationary base. The refrigerant circulation channel includes a portion held in contact with the heat reflector.

Preferably, the heat reflector may surround the guide rail.

Preferably, the portion of the refrigerant circulation channel that is held in contact with the heat reflector may be positioned adjacent to the guide rail.

Preferably, the linear movement mechanism may include a driving pulley and an output belt which is wound around the driving pulley and connected to the hand. The portion of the refrigerant circulation channel that may be held in contact with the heat reflector is positioned adjacent to the output belt.

Preferably, the heat reflector may include a plurality of plates spaced from each other between the hand and the guide rail.

Preferably, the connection space may comprise an annular space defined between the stationary base and the swivel. In such a case, the connection space may comprise first and second annular spaces defined between the stationary base and the swivel, where the first and the second annular spaces are separated from each other by a hermetic seal. Further, the stationary base side passage may include a forward path and a backward path, where the forward path communicates with the first annular space, and the backward path communicates with the second annular space.

### BRIEF DESCRIPTION OF THE DRAWINGS

FIG. 1 is a perspective view showing a transfer apparatus according to the present invention;

FIG. 2 is a plan view of the transfer apparatus shown in FIG. 1;

FIG. 3 is a sectional view taken along lines III-III in FIG. 2;

FIG. 4 is an enlarged sectional view showing part of FIG. 3;

FIG. 5 is a sectional view taken along lines V-V in FIG. 2;

FIG. 6 illustrates the structure of the refrigerant circulation channel; and

FIG. 7 is a sectional view taken along lines VII-VII in FIG. 3.

### DETAILED DESCRIPTION OF THE PREFERRED EMBODIMENTS

Preferred embodiments of the present invention will be described below with reference to the accompanying drawings.

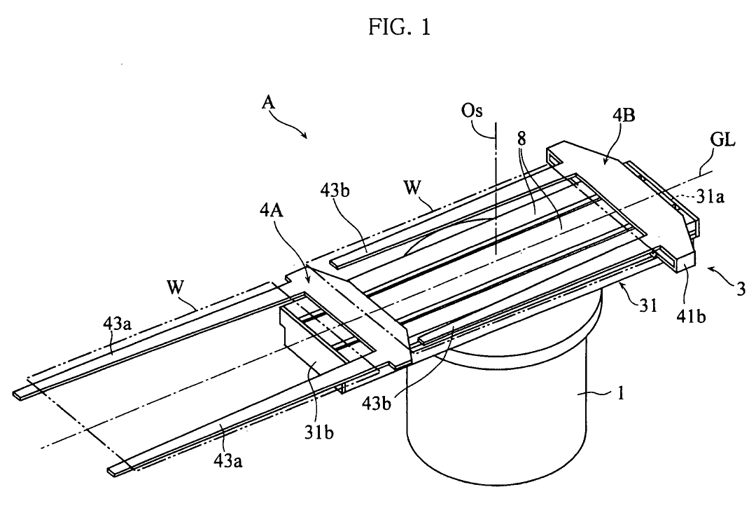

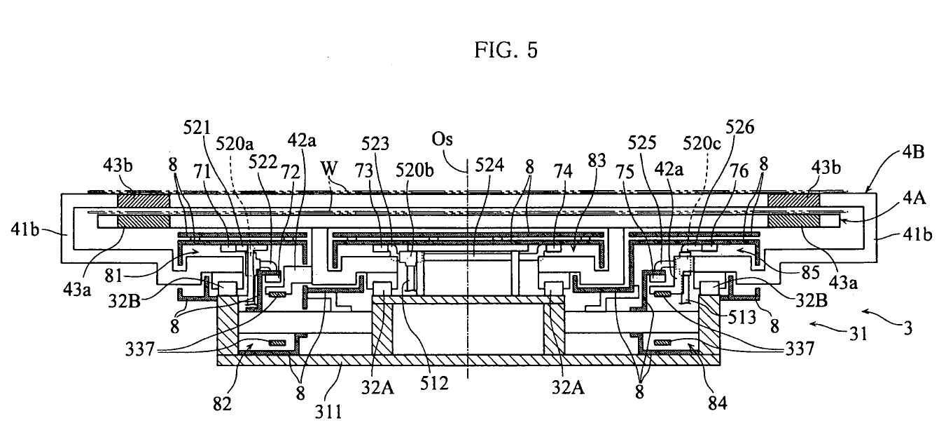

FIGS. 1-7 show a transfer apparatus according to a preferred embodiment of the present invention. The transfer apparatus A is used for transferring a work W in the form of a thin plate such as a substrate used for a liquid crystal display panel. As shown in FIGS. 1-3, the transfer apparatus A includes a stationary base 1, a swivel 2 supported by the stationary base 1 to be rotatable around a vertical rotation axis Os, a linear movement mechanism 3 supported by the swivel 2, and a pair of hands 4A and 4B individually supported by the linear movement mechanism 3. The hands 4A and 4B are configured to hold and carry the work W in a horizontal posture.

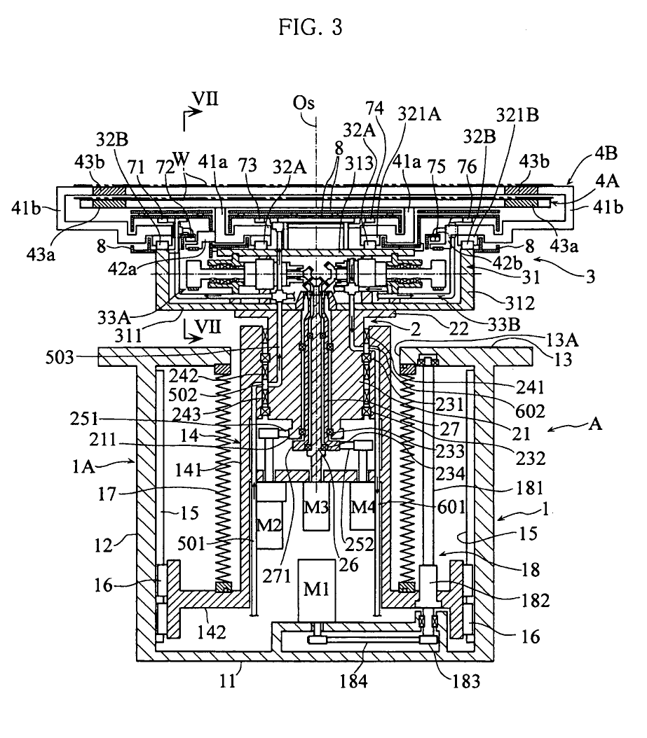

As shown in FIG. 3, the stationary base 1 includes a housing 1A having a generally columnar outer configuration made up of a bottom wall 11, a cylindrical side wall 12 and a top wall 13. The top wall 13 is formed with a center opening 13A.

The stationary base 1 supports therein a lift base 14. The lift base 14 has an outer diameter which is smaller than the center opening 13A and includes a cylindrical portion 141 having a predetermined dimension in the vertical direction and an outward flange 142 formed at the lower end of the cylindrical portion 141. The inner surface of the side wall 12 of the housing 1A is formed with a plurality of linear guide rails 15 extending in the vertical direction. A plurality of guide members 16, provided at the outward flange 142 of the lift base 14, are slidable in the vertical direction relative to the linear guide rails 15. With this arrangement, the lift base 14 is vertically movable relative to the stationary base 1 within a predetermined range. In this movement, the upper part of the cylindrical portion 141 of the lift base 14 projects from the center opening 13A of the housing 1A.

A bellows 17 surrounds the cylindrical portion 141 of the lift base 14, and the upper and the lower ends of the bellows 17 are connected to the top wall 13 of the stationary base 1 and the outward flange 142 of the lift base 14, respectively. The bellows 17 hermetically seals the space between the top wall 13 of the stationary base 1 and the outward flange 142 of the lift base 14 even when the lift base 14 moves vertically.

The stationary base 1 further incorporates a ball screw mechanism 18. The ball screw mechanism 18 includes a screw shaft 181 extending vertically and rotatably arranged outside the bellows 17, and a nut 182 held in thread engagement with the screw shaft 181 and fixed to the outward flange 142 of the lift base 14 in a penetrating manner. A pulley 183 is mounted to the lower end of the screw shaft 181. The screw shaft 181 is connected to a motor M1 via a belt 184 wound around the pulley 183 and rotated in a normal and a reverse direction by the operation of the motor M1. By rotating the screw shaft 181 in this way, the lift base 14 moves up and down.

A refrigerant circulation channel extending continuously through the stationary base 1 and the swivel 2 is provided in the transfer apparatus A. The refrigerant circulation channel is used for supplying cooling medium (hereinafter referred to as refrigerant) to appropriate portions and comprises paths, annular spaces and cooling pipes, which will be described later. In FIGS. 3, 4 and 6, the direction in which the refrigerant flows is indicated by arrows. As the refrigerant, use may be made of gas such as air or helium or liquid such as water.

As shown in FIG. 3, a forward path (supply path) 501 and a backward path (return path) 601 constituting the refrigerant circulation channel are provided in the lift base 14. The lower end of the forward path 501 may be connected to a pump (not shown) for supplying air as the refrigerant provided outside the housing 1A of the stationary base 1. The lower end of the backward path 601 communicates with the outside of the housing 1A to discharge the air to the outside of the transfer apparatus A.

As shown in FIG. 3, the swivel 2 includes a cylindrical shaft 21 and an upper plate 22 integrally connected to the upper end of the cylindrical shaft 21. The cylindrical shaft 21 is supported by the cylindrical portion 141 of the lift base 14 via bearings 231 and 232 to be rotatable around the rotation axis Os. A space is defined between the cylindrical portion 141 and the cylindrical shaft 21. Sealing mechanisms 241, 242 and 243 are arranged in the mentioned order from top to bottom between the cylindrical portion 141 and the cylindrical shaft 121.

A backward annular space 602 is provided between the sealing mechanism 241 and the bearing 231. The annular space 602 is connected to the upper end of the backward path 601. A forward annular space 502 is defined between the sealing mechanism 242 and the sealing mechanism 243. The annular space 502 is connected to the upper end of the forward path 501. The two annular spaces 502 and 602 are separated from each other by the sealing mechanism 242 and structured to circulate the refrigerant without leakage. The sealing mechanisms 241, 242 and 243 prevent the inner space of the cylindrical portion 141 of the lift base 14 from communicating with the outside space and provide air tightness.

A forward path 503 and a backward path 603 constituting the refrigerant circulation channel are provided in the cylindrical shaft 21. The lower ends of the forward and the backward paths 503 and 603 are connected to the forward and the backward annular spaces 502 and 602, respectively. The upper ends of the paths 503 and 603 extend into a guide member 31 of the linear movement mechanism 3, which will be described later.

The cylindrical shaft 21 includes a lower end integrally formed with a pulley 211. A belt 251 is wound between the pulley 211 and a pulley mounted to an output shaft of a motor M2 supported in the cylindrical portion 141. With this arrangement, when the motor M2 is driven, the swivel 2 rotates around the rotation axis Os. When the swivel 2 rotates, the lower ends of the paths 503 and 603 move along the annular spaces 502 and 602, respectively. Thus, the paths 503 and 603 constantly communicate with the paths 501 and 601 via the annular spaces 502 and 602, respectively, regardless of the rotational position of the swivel 2 relative to the stationary base 1.

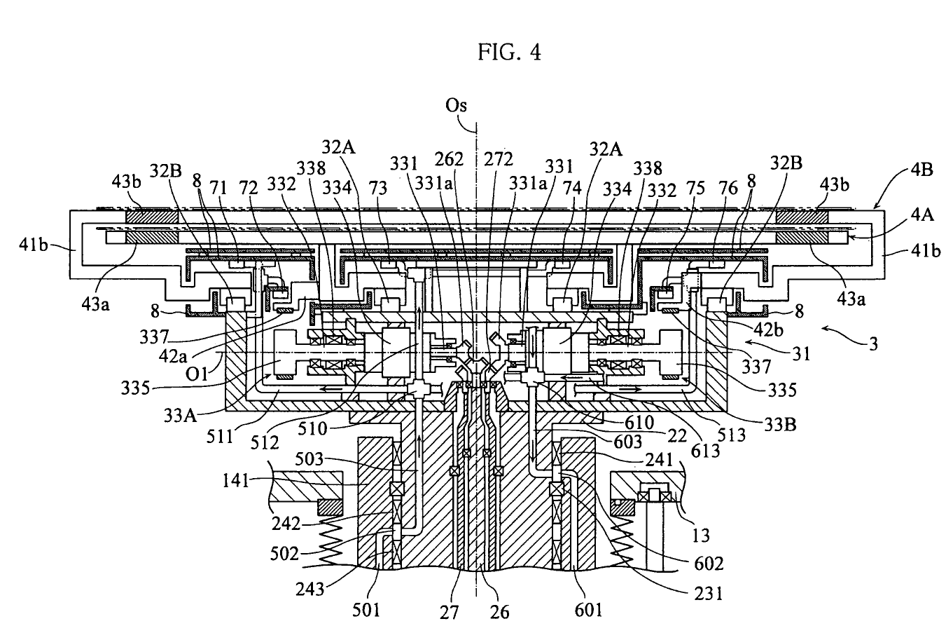

As shown in FIGS. 3 and 4, a first and a second transmission shafts 26 and 27 for transmitting driving force to a first and a second driving mechanisms 33A and 33B, which will be described later, are provided to extend within the cylindrical shaft 21 of the swivel 2 coaxially along the rotation axis Os. The second transmission shaft 27 is cylindrical and rotatably supported within the cylindrical shaft 21 via a bearing 233. The first transmission shaft 26 is rotatably supported within the second transmission shaft 27 via a bearing 234. The lower end of the first transmission shaft 26 is connected to the output shaft of a motor M3 supported within the cylindrical portion 141. The upper end of the first transmission shaft 26 is provided with a bevel gear 262. The lower end of the second transmission shaft 27 is provided with a pulley 271. A belt 252 is wound between the pulley 271 and a pulley mounted to the output shaft of a motor M4 supported within the cylindrical portion 141. A bevel gear 272 is mounted to the upper end of the second transmission shaft 27.

The linear movement mechanism 3 serves to transfer the hands 4A, 4B along a horizontal straight travel path GL. As shown in FIG. 3, the linear movement mechanism 3 includes a guide member 31, a pair of inner guide rails 32A and a pair of outer guide rails 32B provided on the guide member 31, and the first and the second driving mechanisms 33A, 33B for transmitting horizontal driving force to the hands 4A, 4B.

The guide member 31 is in the form of an elongated rectangle having a horizontally-extending longitudinal axis (travel path GL) and includes a bottom wall 311, side walls 312 and a top wall 313. The guide member 31 is fixed to the upper plate 22 of the swivel 2 so that the guide member rotates when the swivel 2 rotates. The space between the bottom wall 311 of the guide member 31 and the upper plate 22 of the swivel 2 is hermetically sealed by a non-illustrated sealing member. The paired inner guide rails 32A are supported by the top wall 313, whereas the paired outer guide rails 32B are supported by the side walls 312.

As shown in FIGS. 3 and 4, the hand 4A is supported by the inner guide rails 32A via a pair of support arms 41a formed on the lower surface thereof and a slider 321A provided on the support arms 41a. The support arms 41a are provided with a connection member 42a, which is connected to an output belt 337 of the first driving mechanism 33A, which will be described later. The hand 4B is supported by the outer guide rails 32B via a pair of support arms 41b formed outward the sides of the hands 4A and a slider 321B provided on the support arm 41b. The support arms 41b are provided with a connection member 42b, which is connected to an output belt 337 of the second driving mechanism 33B, which will be described later.

As better shown in FIGS. 1-3, the hands 4A and 4B are integrally formed with holder pieces 43a and 43b in the form of a fork extending in the longitudinal direction of the guide member 31. The holder pieces 43a, 43b are utilized for holding a work W in the form of a thin plate placed thereon. Unlike FIGS. 1 and 2, FIGS. 3-5 show the state in which both of the hands 4A and 4B are positioned above the stationary base 1.

As shown in FIGS. 3-5, a heat reflector 8 is provided at the guide member 31 via supporting means. When a heated work W is placed on the holder pieces 43a, 43b of the hands 4A, 4B, the heat reflector 8 serves to reflect the heat from the work W. The heat reflector 8 is made up of a plurality of heat reflection plates arranged so as not to come into contact with the support arms 41a, 41b and the connection members 42a, 42b of the hands 4A, 4B. The heat reflector or heat reflection plates 8 are arranged to surround the inner guide rails 32A, the outer guide rails 32B and the output belts 337 of the first and the second driving mechanisms 33A and 33B. The thus arranged heat reflection plates 8 and the guide member 31 define spatial sections 81-85. The heat reflection plates 8 may be made of stainless steel. Some of the heat reflection plates 8 are arranged in a horizontal posture between the hands 4A, 4B and the guide rails 32A, 32B, thereby serving to block the heat coming directly downward from the hands 4A, 4B. Specifically, a plurality of mutually spaced pieces (two pieces in this embodiment) of the heat reflection plates 8 are arranged between the hands 4A, 4B and the guide rails 32A, 32B in an overlapping manner as viewed in the direction proceeding away from the hands 4A, 4B (direction along the rotation axis Os).

As shown in FIGS. 4-6, forward paths 511-513, 521-526, backward paths 611-613, 621-626 and cooling pipes 71-76 constituting the refrigerant circulation channel are provided in the guide member 31 and the sections 81-85. These members are so arranged as not to come into contact with the support arms 41a, 41b and the connection members 42a, 42b of the hands 4A, 4B. The cooling pipes 71-76 are held in contact with part of the heat reflector 8. The cooling pipes 73 and 74 are arranged adjacent to and in parallel with the guide rails 32A. The cooling pipes 71 and 76 are arranged adjacent to and in parallel with the guide rails 32B. The cooling pipes 72 and 75 are arranged adjacent to and in parallel with the output belts 337 of the first and the second driving mechanisms 33A and 33B, respectively.

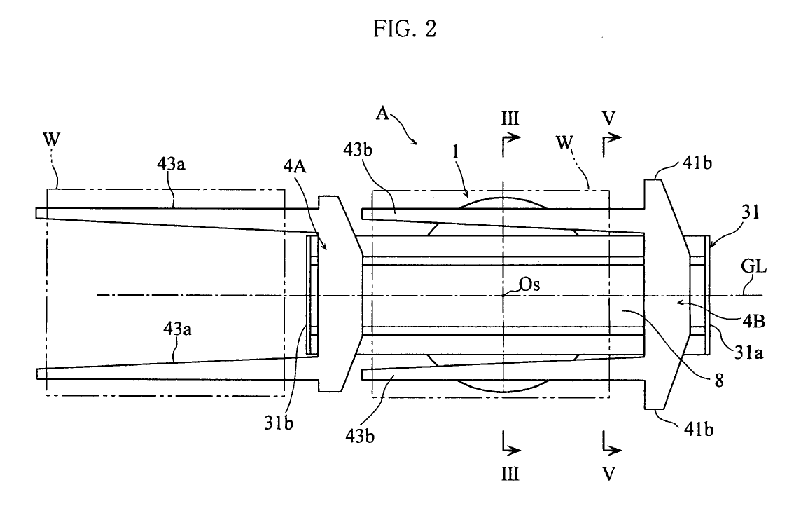

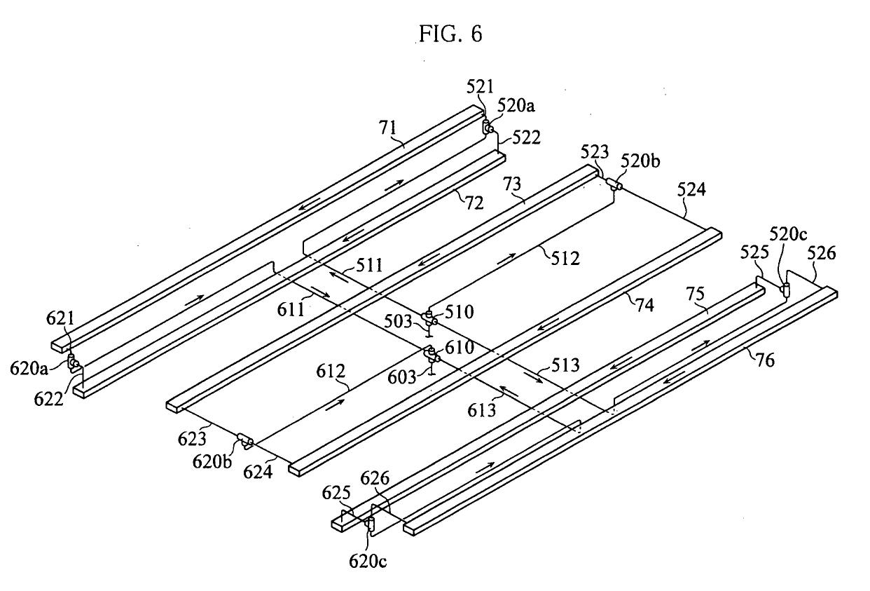

As schematically shown in FIG. 6, forward paths 521-526 are connected to first ends (the ends on the front end 31a side of the guide member 31 shown in FIGS. 1 and 2) of the cooling pipes 71-76, respectively. The paths 521 and 522 connected to the cooling pipes 71 and 72, respectively, are connected to the path 511 via a joint 520a provided on the front end 31a side of the guide member 31. Similarly, the paths 523 and 524 connected to the cooling pipes 73 and 74, respectively, are connected to the path 512 via a joint 520b. The paths 525 and 526 connected to the cooling pipes 75 and 76, respectively, are connected to the path 513 via a joint 520c. The paths 511, 512 and 513 are connected to the path 503 via a joint 510 provided adjacent to the center of the guide member 31.

Backward paths 621-626 are connected to second ends (the ends on the rear end 31b side of the guide member 31) of the cooling pipes 71-76, respectively. The paths 621 and 622 connected to the cooling pipes 71 and 72, respectively, are connected to the path 611 via a joint 620a provided on the rear end 31b side of the guide member 31. Similarly, the paths 623 and 624 connected to the cooling pipes 73 and 74, respectively, are connected to the path 612 via a joint 620b. The paths 625 and 626 connected to the cooling pipes 75 and 76, respectively, are connected to the path 613 via a joint 620c. The paths 611, 612 and 613 are connected to the path 603 via a joint 610 provided adjacent to the center of the guide member 31.

The refrigerant circulation channel is made up of an appropriate number of paths or passages, some of which may be formed directly in components of the transfer apparatus, and others of which may be provided by metal pipes, for example. These paths and pipes are hermetically connected to each other. In the refrigerant circulation channel, when the refrigerant is supplied from the non-illustrated pump to the path 501, the refrigerant flows through the annular space 502, the path 503, the paths 511-513, the paths 521-526, the cooling pipes 71-76, the paths 621-626, the paths 611-613, the path 603, the annular space 602 and the path 601 in the mentioned order to be discharged from the transfer apparatus A.

The first and the second driving mechanisms 33A and 33B serve to move the hands 4A and 4B individually along the travel path GL. The first and the second driving mechanisms 33A and 33B basically have the same structure. Thus, only the structure of the first driving mechanism 33A will be described below, and the description of the second driving mechanism 33B will be omitted appropriately.

As shown in FIG. 4, the first driving mechanism 33A includes transmission shafts 331, 332, a deceleration mechanism 334, a driving pulley 335 and an output belt 337. The first driving mechanism 33A is accommodated in the guide member 31. The transmission shaft 331 is supported by the guide member 31 rotatably around a horizontal axis O1 extending perpendicularly to the rotation axis Os. A bevel gear 331a is mounted to an end (right end in the figure) of the transmission shaft 331. The bevel gear 331a meshes with a bevel gear 262 mounted to an upper end of the first transmission shaft 26. The other end of the transmission shaft 331 is connected to the input shaft of the deceleration mechanism 334.

The transmission shaft 332 is supported by the guide member 31 rotatably around the horizontal axis O1. An end of the transmission shaft 332 is connected to the output shaft of the deceleration mechanism 334. The driving pulley 335 is mounted to the other end (left end in the figure) of the transmission shaft 332. A sealing mechanism 338 intervenes between the transmission shaft 332 and the guide member 31. By the provision of the sealing mechanism 338, the inner space of the lift base 14 communicating with the inside of the guide member 31 via the swivel 2 is hermetically sealed from the outside. A coupling joint (not shown) may be provided as required between the transmission shaft 331 and the transmission shaft 332.

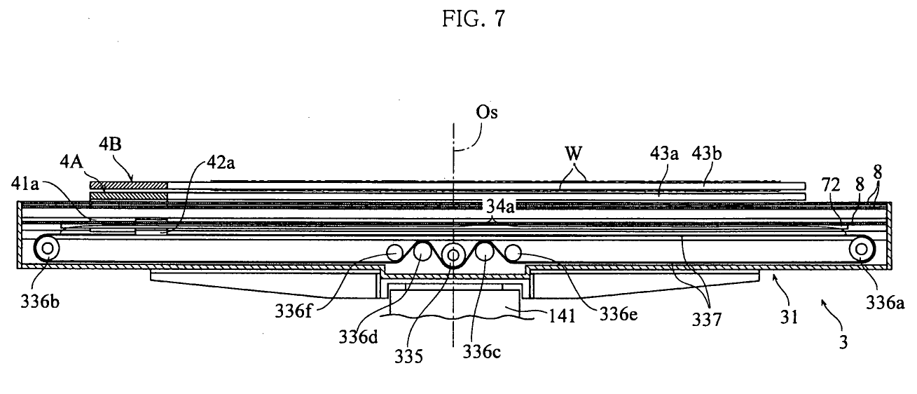

As shown in FIG. 7, the output belt 337 is wound around the driving pulley 335 and the pulleys 336a-336f to lie within a vertical plane. The pulleys 336a and 336b are provided adjacent to the ends of the guide member 31 which are opposite in the longitudinal direction (the direction along the travel path GL). The pulleys 336c, 336d, 336e, 336f are provided adjacent to the driving pulley 335, and the pulleys 336c and 336d are arranged outside the output belt 337. Thus, appropriate tension is applied to the output belt 337. As the output belt 337, a timing belt may be suitably used.

With the above-described arrangement, when the motor M3 is driven, the rotational driving force of the motor M3 is transmitted to the first driving mechanism 33A via the first transmission shaft 26. In the driving mechanism 33A, the rotation around the rotation axis Os is converted into the rotation around the horizontal axis O1 by the bevel gears 262 and 331a, and deceleration is performed by the deceleration mechanism 334, whereby the driving pulley 335 is rotated. In accordance with the rotation of the driving pulley 335, the output belt 337 reciprocates within a predetermined vertical plane.

The pulleys 336a and 336b are arranged along a line extending parallel to the travel path GL. In FIG. 7, the region of the output belt 337 which is positioned above the pulleys 336a and 336b is a section 34a extending parallel to the travel path GL, and the output belt 337 reciprocates within the section 34a. The connection member 42a extending from the support arm 41a of the hand 4A is connected to a predetermined portion of the section 34a of the output belt 337. With this arrangement, by the operation of the first driving mechanism 33A, the hand 4A slides horizontally along the travel path GL while being supported by the two inner guide rails 32A.

As shown in FIG. 4, the transmission shafts 331 and 332 of the second driving mechanism 33B are arranged to face the transmission shafts 331 and 332 of the first driving mechanism 33A across the rotation axis Os and rotatable around the horizontal axis O1. A bevel gear 331a is mounted to an end (left end in the figure) of the transmission shaft 331. The bevel gear 331a meshes with a bevel gear 272 mounted to an upper end of the second transmission shaft 27. With the above-described arrangement, when the motor M4 is driven, the rotational driving force of the motor M4 is transmitted to the second driving mechanism 33B via the belt 252 and the second transmission shaft 27. In the driving mechanism 33B, the rotation around the rotation axis Os is converted into the rotation around the horizontal axis O1 by the bevel gears 272 and 331a, and deceleration is performed by the deceleration mechanism 334, whereby the driving pulley 335 is rotated. In accordance with the rotation of the driving pulley 335, the output belt 337 reciprocates within a predetermined vertical plane. The connection member 42b extending from the support arm 41b of the hand 4B is connected to a predetermined portion of the output belt 337. With this arrangement, by the operation of the second driving mechanism 33B, the hand 4B slides horizontally along the travel path GL while being supported by the two outer guide rails 32B.

For instance, the transfer apparatus A having the above-described structure may be used for carrying in or out a work relative to a process chamber in the process of manufacturing a liquid crystal display panel. In this case, for instance, the transfer apparatus A may be placed in a transport chamber in a vacuum around which a plurality of process chambers are arranged.

The transfer apparatus A may be operated to repetitively transfer a work W such as a glass substrate heated to about 250 to 400° C. in a vacuum. In such a case, the guide rails 32A and 32B are susceptible to radiation heat from the work W. When the guide rails 32A, 32B are heated to a high temperature due to the radiation heat, the dimension of the guide rails may change greatly or the guide rails may be deformed due to thermal expansion. In this case, the transfer accuracy of the apparatus may be deteriorated or the proper transfer of the work W may be hindered.

In the transfer apparatus A of this embodiment, however, the heat reflector 8 for reflecting the heat from the work W held by the hands 4A and 4B is provided between the hands 4A, 4B and the guide rails 32A, 32B. Thus, the heat radiated from the work W is reflected by the heat reflector 8, whereby the guide rails 32A and 32B are prevented from being heated by the heat from the work W. Particularly, since a plurality of pieces of the reflection plate 8 are arranged between the hands 4A, 4B and the guide rails 32A, 32B in an overlapping manner in the direction away from the hands 4A, 4B, the radiation heat traveling straight from the work W toward the guide rails 32A, 32B is effectively reflected.

Further, cooling pipes 73, 74, 71, 76 for the flow of the cooling medium are provided on the lower surface of the heat reflector 8 at locations adjacent to the guide rails 32A, 32B. Thus, even when the radiation heat from the work W is absorbed by the heat reflector 8, the absorbed heat is quickly released to the outside of the transfer apparatus A by the refrigerant in the cooling pipes 73, 74, 71, 76. Thus, the guide rails 32A, 32B are prevented from being excessively heated. Further, in this embodiment, cooling pipes 72, 75 are also provided on the lower surface side of the heat reflector 8 at locations adjacent to the output belt 337 of the belt-type driving mechanisms 33A, 33B. Thus, the output belt 337 is also prevented from being excessively heated, whereby the thermal expansion of the output belt 337 and the resulting deterioration of the transfer accuracy are prevented.

In the transfer apparatus A, the sections 81-85 are defined by the heat reflector 8 and the guide member 31, and the guide rails 32A, 32B, the output belt 337 and the cooling pipes 71-76 are arranged in the sections 81-85. With this arrangement, the ambient temperature in the sections 81-85, i.e., the temperature around the guide rails 32A, 32B and the output belt 337 is kept lower than the temperature outside the sections 81-85. This also contributes to the prevention of the excessive heating of the guide rails 32A, 32B and the output belt 337.

In this way, with the structure of this embodiment, even in transferring a heated work W by the transfer apparatus A, the heat reflector 8 prevents the heat radiated from the work W from being conducted to the guide rails 32A, 32B and the output belt 337, and the refrigerant circulation channel keeps the temperature around the guide rails 32A, 32B and the output belt 337 lower than the outside temperature. Thus, the guide rails 32A, 32B and the output belt 337 are prevented from being heated to such a degree that they are thermally expanded to result in a large dimensional error. Thus, the hands 4A and 4B operate accurately to transfer the heated work W accurately and smoothly in a vacuum.

Although the embodiments of the present invention are described above, the present invention is not limited thereto. The specific structure of each part of the transfer apparatus according to the present invention may be varied in various ways without departing from the spirit of the invention.

For instance, as the linear movement mechanism, a link arm mechanism (See the transfer apparatus disclosed in the Patent Document 1) may be employed instead of the mechanism driven by a belt like the above-described embodiment. In this case, the cooling pipes constituting the refrigerant circulation channel need to be provided only at the locations adjacent to the guide rails.

The hand for carrying a work does not necessarily have the structure including two hands 4A and 4B like the foregoing embodiments but may have a one-hand structure.

Although the foregoing embodiments are described on the assumption that the transfer apparatus is to be used in a vacuum, the transfer apparatus according to the present invention may be designed for use under atmospheric pressure.

1. A transfer apparatus comprising:
a stationary base;
a swivel rotatably supported by the stationary base;
a linear movement mechanism supported by the swivel and including a guide rail;
a hand supported by the guide rail for transferring a work along a horizontal straight travel path by operation of the linear movement mechanism;
a heat reflector for reflecting heat from the hand, the heat reflector being arranged at least between the hand and the guide rail; and
a refrigerant circulation channel extending through both the stationary base and the swivel;
wherein the refrigerant circulation channel includes a stationary base side passage provided at the stationary base, a swivel side passage provided at the swivel, and a connection space for providing communication between the stationary base side passage and the swivel side passage regardless of a rotational position of the swivel relative to the stationary base, and wherein the refrigerant circulation channel includes a portion held in contact with the heat reflector.

2. The transfer apparatus according to claim 1, wherein the heat reflector surrounds the guide rail.

3. The transfer apparatus according to claim 1, wherein the portion of the refrigerant circulation channel that is held in contact with the heat reflector is positioned adjacent to the guide rail.

4. The transfer apparatus according to claim 1, wherein the linear movement mechanism includes a driving pulley and an output belt wound around the driving pulley and connected to the hand, and wherein the portion of the refrigerant circulation channel that is held in contact with the heat reflector is positioned adjacent to the output belt.

5. The transfer apparatus according to claim 1, wherein the heat reflector includes a plurality of plates spaced from each other between the hand and the guide rail.

6. The transfer apparatus according to claim 1, wherein the connection space comprises an annular space defined between the stationary base and the swivel.

7. The transfer apparatus according to claim 1, wherein the connection space comprises first and second annular spaces defined between the stationary base and the swivel, the first and the second annular spaces being separated from each other by a hermetic seal, and wherein the stationary base side passage includes a forward path and a backward path, the forward path communicating with the first annular space, the backward path communicating with the second annular space.
